(19) United States
(12) Patent Application Publication
(10) Pub. No.: US 2015/0194322 A1
(43) Pub. Date: Jul. 9, 2015

(54) LEAD CARRIER WITH THERMALLY FUSED PACKAGE COMPONENTS

(71) Applicant: EoPlex Limited, Hong Kong (CN)

(72) Inventor: Philip E. Rogren, Half Moon Bay, CA (US)

(21) Appl. No.: 14/662,841

(22) Filed: Mar. 19, 2015

Related U.S. Application Data
(62) Division of application No. 13/540,903, filed on Jul. 3, 2012.

(51) Int. Cl. H01L 21/48; H01L 23/00

(52) U.S. Cl. CPC H01L 21/4828; H01L 24/85; H01L 24/83

(57) ABSTRACT

A lead carrier provides support for a semiconductor device during manufacture. The lead carrier includes a temporary support member with multiple package sites. Each package site includes a die attach pad surrounded by a plurality of terminal pads. The pads are formed of a fusible fixing material on a lower portion. A chip is mounted upon the die attach pad and wire bonds extend from the chip to the terminal pads. The pads, chip and wire bonds are all encapsulated within a mold compound. The temporary support member can be heated above a melting temperature of the fusible fixing material and peeled away and then the individual package sites can be isolated from each other to provide completed packages including multiple surface mount joints for mounting within an electronics system board.

### CROSS-REFERENCE TO RELATED APPLICATIONS

This application is a divisional of U.S. patent application Ser. No. 13/540,903, filed on Jul. 3, 2012 which claims benefit under Title 35, United States Code §119(e) of U.S. Provisional Application No. 61/504,225 filed on Jul. 3, 2011.

### FIELD OF THE INVENTION

The following invention relates to lead carrier packages for use with an integrated circuit chip for effective interconnection of the integrated circuit chip in an electrical system. More particularly, this invention relates to lead frames and other lead carriers which are manufactured as an array of multiple package sites within a common assembly before and during combination with the integrated circuit, attachment of wire bonds and encapsulation within non-conductive material, before isolation into individual packages for use upon an electronics system board, such as a printed circuit board.

### BACKGROUND OF THE INVENTION

The demand for smaller and more capable, portable electronic systems, combined with the increased level of integration in today's semiconductors, is driving a need for smaller semiconductor packages with greater numbers of input/output terminals. At the same time, there is relentless pressure to reduce the cost of all the components of consumer electronic systems. The quad flat no lead (“QFN”) semiconductor package family is among the smallest and most cost effective of all semiconductor packaging types, but when fabricated with conventional techniques and materials, has significant limitations. For instance, with QFN technology the number of I/O terminals and the electrical performance that the technology can support is limited.

QFN packages P (FIGS. 5-7) are conventionally assembled on an area array lead frame 1 (FIGS. 1 and 2) etched from a copper sheet. A lead frame 1 can contain from tens to thousands of package sites, each comprised of a die attach pad 2 (FIGS. 1, 2 and 5-7) surrounded by one or more rows of wire bond pads 4 (FIGS. 2 and 5-7). All of these package P components are attached to a common frame 1 by pieces of copper to maintain the position of the package P components relative to the rest of the lead frame 1 and to provide an electrical connection to all of the components, to facilitate plating of the bonding and soldering surfaces.

These connected structures, commonly known as tie bars 3 (FIGS. 1, 2 and 5-7) short all of the components of the lead frame 1 together. Therefore, these tie bars 3 must be designed such that they can all be disconnected from the common shorting structure 6 (FIGS. 1 and 2) surrounding each package P site during singulation of the individual packages P from the lead frame 1, leaving each die attach pad 2 and wire bond pad 4 electrically isolated. Typically, the design to facilitate severing the electrical connection of the tie bars 3 to the lead frame 1 involves connecting the tie bars 3 to the copper shorting structure 6 (FIGS. 1 and 2) surrounding each package P site, just outside of the final package P footprint. This shorting structure 6 is sawn away (along line X of FIG. 2) during the singulation process, leaving the tie bars 3 exposed at the edge of the package P.

The QFN lead frame 1 provides the parts of the package P that facilitate fixing the semiconductor die, such as an integrated circuit chip 7 (FIGS. 5-7) within the package P and the terminals that can be connected to the integrated circuit 7 through wire bonds 8 (FIGS. 5 and 6). The terminals, in the form of the wire bond pads 4, also provide a means of connecting to the electronic system board (such as a printed circuit board) through a solder joint 5 (FIGS. 5-7) on the surface opposite that of the wire bond 8 surface.

The requirement that all of the package P components be connected to the lead frame 1 by a metal structure, severely limits the number of leads that can be implemented in any given package P outline. For instance, wire bond pads 4 can be provided in multiple rows surrounding the die attach pads 2 with each row being a different distance away from the die attach pads 2. For any wire bond pads 4 inside the outermost row of wire bond pads 4, the tie bar 3 connecting structures must be routed between the pads 4 of the outer row, so that such tie bars 3 can extend to the common sorting structure 6 outboard of the package P isolation (along line X). The minimum scale of these tie bars 3 is such that only one can be routed between two adjacent pads 4. Thus, only two rows of pads 4 may be implemented in a standard QFN lead frame 1. Because of the current relationship between die size and lead count, standard QFN packages are limited to around one hundred terminals, with a majority of packages P having no more than about sixty terminals. This limitation rules out the use of QFN packaging by many types of dies that would otherwise benefit from the smaller size and lower cost of QFN technology.

While conventional QFN technology is very cost effective, there are still opportunities to further reduce the cost. After the integrated circuit chips 7 are attached and connected to the external lead wire bond pads 4 with wire bonds 8, the assembled lead frame 1 of multiple packages P is completely encapsulated with epoxy mold compound 9 (FIGS. 6 and 7), such as in a transfer molding process. Because the lead frame 1 is largely open front to back, a layer of high temperature tape T is applied to the back of the lead frame 1, prior to the assembly process, to define the back plane of each package P during molding. Because this tape T must withstand the high temperature bonding and the molding process, without adverse effect from the hot processes, the tape is relatively expensive. The process of applying the tape T, removing the tape T and removing adhesive residues, can add significant cost to processing each lead frame 1.

The most common method of singulation of the individual packages P from the lead frame 1 is by sawing (along line X of FIG. 2). Because the saw must remove all of the shorting structures 6 just outside the package P outline, in addition to cutting the epoxy mold compound 9, the process is substantially slower and blade life considerably shorter, as if only mold compound 9 is cut. Because the shorting structures 6 are not removed until the singulation process, this means that the dies cannot be tested until after singulation. Handling thousands of tiny packages P, and assuring each is presented to the tester in the correct orientation is much more expensive than being able to test the whole strip with each passage P in a known location.

A lead frame 1 based process, known as punch singulation, to some extent addresses the problem associated with saw singulation and allows testing in the lead frame 1 strip, but substantially increases cost by cutting utilization of the lead frame 1 to less than fifty percent of that of a saw singulated lead frame 1. Punch singulation also imposes a requirement for dedicated mold tooling for every basic lead frame design. Standard lead frames 1 designed for saw singulation use a single mold cap for all lead frames 1 of the same dimensions.

In both saw singulated and punch singulated packages P, the tie bars 3 are left in the completed packages P and represent both capacitive and inductive parasitic elements that cannot be removed. These now superfluous pieces of metal significantly impact the performance of the completed package P, precluding the use of QFN packages P for many high performance integrated circuit chips 7 and applications. Furthermore, the cost of this potentially rather valuable superfluous metal can be substantial and is wasted by the QFN process.

Several concepts have been advanced for QFN type substrates that eliminate the limitations of etched lead frames. Among those is a process that deposits the array of package components on a sacrificial carrier by electroplating. The carrier is first patterned with plating resist and the carrier, usually stainless steel, is slightly etched to enhance adhesion. The strip is then plated with gold and palladium to create an adhesion/barrier layer, then plated with Ni to around sixty microns thick. The top of the Ni bump is finished with a layer of electroplated Ag to facilitate wire bonding. After the strip is assembled and molded, the carrier strip is peeled away to leave a sheet of packaged dies that can be tested in the sheet and singulated at higher rates and yields than with conventional lead frames. This electroplated approach eliminates all of the issues associated with connective metal structures within the package and allows for very fine features. The plating process, however, results in strips that are very expensive compared to standard etched lead frames. This approach is described in U.S. Pat. No. 7,187,072 by Fukutomi, et al.

Another approach is a modification of the etched lead frame process wherein the front side pattern is etched to about half the thickness of the lead frame, and the backside of the lead frame strip is left intact, until after the molding process is complete. Once molding is complete, the backside pattern is printed and the lead frame etched to remove all of the metal except for the backside portion of the wire bond pads and die paddle. This double etch process eliminates all of the issues associated with connective metal structures within the package. The cost of the double etched lead frame is less than the electroplated version, but still more expensive than standard etched lead frames, and the etching and plating processes are environmentally undesirable.

One failure mode for a lead frame packaged integrated circuit is for the wire bond pads 4 to become disconnected from wire bonds 8 coupled thereto, especially when a shock load is experienced by the package (such as when an electronic device incorporating the package therein is dropped and hits a hard surface). The wire bond pad 4 can remain mounted to a printed circuit board or other electronic system board while separating slightly from surrounding epoxy mold compound, allowing the wire bond 8 to be severed from the wire bond pad 4. Accordingly, a further need exists for a lead carrier package which better holds the wire bond pads 4 within the entire package, especially when shock loads are experienced.

Another lead carrier known in the art and developed by Eoplex, Inc. of Redwood City, Calif. is known as a lead carrier with print-formed package components and is the subject of U.S. patent application Ser. No. 13/135,210, incorporated by reference herein in its entirety. This lead carrier with print-formed components is provided with an array of separate package sites in the form of a multi-package lead carrier (see for example FIGS. 3 and 4 for a general depiction of one form of this lead carrier). A sintered material, typically beginning as silver powder, is placed upon a temporary layer formed of high temperature resistant material, such as stainless steel. The stainless steel or other material forming the temporary layer supports the sintered material while it is heated to a sintering temperature.

The sintered material is located upon the temporary layer in separate structures preferably electrically isolated from each other (other than through the temporary layer) in the form of die attach pads and terminal pads. One or more terminal pads surround each die attach pad. Each die attach pad is configured to have an integrated circuit or other semiconductor device supported thereon. Wire bonds can be routed from the integrated circuit upon the die attach pad to the separate terminal pads surrounding each die attach pad (see for example FIG. 8). Mold compound can then be applied which encapsulates the die attach pads, integrated circuits, terminal pads and wire bonds (see for example FIGS. 9 and 10). Only surface mount joints defining under portions of the die attach pad and terminal pads remain unencapsulated (FIG. 10) because they are adjacent the temporary layer.

Once the mold compound of the lead carrier has hardened, the temporary layer can be peeled away from the remaining portions of the lead carrier, leaving a plurality of package sites with individual die attach pads and associated integrated circuits, terminal pads and wire bonds all embedded within a common mold compound. The individual package sites can then be cut from each other by cutting along boundaries between the package sites and surface mounted through the surface mount joints to an electronics system board or other support.

Because the package sites of the lead carrier and individual pads within the package sites are each electrically isolated from each other, other than through the temporary layer, these individual pads can be tested for electrical continuity while on the temporary layer. After removal of the temporary layer, but before singulation into separate packages, a variety of electrical performance characteristics can be tested. Furthermore, such packages could be tested after isolation from adjacent packages on the lead carrier utilizing known testing equipment utilized with QFN packages or other testing equipment.

Additionally, each pad of the lead carrier, including the die attach pads and the terminal pads, preferably has edges around peripheries thereof which are configured to mechanically engage with the mold compound somewhat. In particular, these edges can taper in an overhanging fashion, or be stepped in an overhanging fashion, or otherwise be configured so that at least a portion of each edge spaced from a bottom thereof extends further laterally than portions of each edge closer to a bottom portion of each edge. Thus, the mold compound, once hardened, locks the pads securely into the mold compound. In this way, the pads resist detachment from the wire bonds or otherwise becoming detached from the mold compound, especially when the temporary layer is peeled away, and keep the entire package as a single unitary package.

### SUMMARY OF THE INVENTION

With this invention a lead carrier is provided with an array of separate package sites in the form of a multi-package lead carrier. Each package site includes at least one die attach pad and at least one terminal pad, but typically includes multiple rows of multiple terminal pads surrounding each die attach pad. The pads are affixed to a temporary support layer formed of a material compatible with the requirements of the semiconductor assembly processes, such as steel or a steel alloy or stainless steel. The means of fixing the die attach pads and the wire bond pads to the temporary layer is a fusible fixing material. The fusible fixing material is selected to have a melting point above temperatures common is semiconductor assembly operations, but which will melt (or at least partially begin fusion) at a temperature below any temperature at which damage would be caused to the semiconductor device or any of the materials used in the assembly processes.

The fusible fixing material is one that will protect the surface to which it is attached from oxidation and corrosion, and promote solder wetting to said surface for an extended period of time. The fusible fixing material can be chosen from the group including tin and alloys of tin and other metals, alloys of gold, alloys of lead, and other metals and metal alloys with melting temperatures between 150° C. and 400° C. Another option for the fusible fixing material is that it be a polymeric composition or other composition (e.g. a paraffin) suitable to protect adjacent surfaces from oxidation and corrosion, and typically having a similar range of melting temperatures.

Each die attach pad is configured to have at least one semiconductor (such as an integrated circuit chip) supported thereon. Wire bonds can be routed from the semiconductor upon the die attach pad to the separate terminal pads arrayed in proximity to the die attach pad. Mold compound can then be applied which encapsulates the die attach pads, semiconductor, terminal pads and wire bond pads. Only surface mount joints defining under portions of the die attach pads and terminal pads remain unencapsulated because they are adjacent to the temporary support layer.

Once the mold compound has hardened, the result is an array, in the form of a sheet, of fully packaged but not yet fully separated, semiconductor devices, attached to the temporary support layer by a fusible fixing material. The temporary layer is separated from the array of packaged semiconductor devices by heating the temporary layer to the melting point of the fusible fixing material and peeling (or otherwise removing) the temporary layer away from the array of packaged semiconductor devices. A coating of the fusible fixing material remains on the surface mount joints, thus protecting them from oxidation or corrosion and promoting good solder wetting during the surface mount assembly processes.

After removal of the temporary layer, the separate ones of the array of packaged semiconductor devices remain physically attached to each other in a continuous sheet, but each of packaged semiconductor devices (and the individual pads within each packaged semiconductor device) are electrically isolated except through the semiconductor (e.g. the integrated circuit chip) itself, and the package terminals are exposed. This configuration allows for testing the separate ones of semiconductor devices while in the continuous sheet of the array by using either a bed of nails type of prober or a step-and-repeat type prober. Singulation by sawing between the separate ones of the array of packaged semiconductor devices yields a plurality of fully packaged and tested semiconductor devices, ready for use in a surface mount assembly process.

Portions of the die pads and the terminal pads above the fusible fixing material are comprised of a highly conductive metal that is compatible with conventional processes for semiconductor die attach, gold or copper thermo sonic wire bonding and SMT soldering. One preferred metal is copper or alloys of copper, but metals, and alloys of metals such as nickel, iron, tungsten, palladium, platinum, gold, silver and aluminum are also possible.

Additionally, each pad including the die attach pads and the terminal pads preferably has edges around peripheries thereof which are configured to mechanically engage with the mold compound somewhat. In particular, these edges can taper in an overhanging fashion, or have a protruding fin, or otherwise be configured so that at least a portion of each edge spaced from a bottom thereof extends further laterally than portions of each edge closer to a bottom portion of each edge. Thus, the mold compound, once hardened, locks the pads securely into the mold compound. In this way, the pads resist detachment from the wire bonds or otherwise becoming detached from the mold compound, and keep the entire package as a single unitary package.

This invention also defines a method for forming the lead carrier of multiple semiconductor package sites. The method begins by supplying a donor sheet of the material from which is formed the portions of the die attach pads and the terminal pads above the fusible fixing material. This sheet is referred to as the donor sheet. A removable mold is applied to a lower surface mounting side of this donor sheet. In one embodiment this mold layer is formed by first applying a photo imageable material to the lower surface of the donor sheet. A photo mask is then placed upon portions of the photo imageable material. A photo etching process is then utilized to form recesses in the photo imageable material.

Once this mold has been put in place, the fusible fixing material is placed into these recesses in the mold layer. One option for such fusible fixing material placement is to use electroplating or electroless deposition. The pattern in the photo mask would generally correspond to the desired locations for die attach pads and terminal pads for each package site. Thus, the fusible fixing material is applied where desired to define a lower surface of each die attach pad and terminal pad upon the donor sheet.

Next, the lower surface of the donor sheet is etched such as with a chemical etching process. This etching process etches away remaining portions of the mold material and etches at least partially into the donor sheet. Preferably, this etching depth is approximately half and actually slightly more than half of a thickness of the donor sheet, and could optionally involve etching entirely through the donor sheet. The etching chemistry or other methodology can be selected so that the material forming the fusible fixing material is not substantially etched by the etching material or process, or some form of etch resist can first be printed or otherwise applied to the fusible fixing material to cause it to resist removal during this donor sheet etching process.

The etched donor sheet with included fusible fixing material on the lower surface thereof is then attached to the temporary support member. This attachment preferably occurs by heating the donor sheet fusible fixing material to a temperature of which the fusible fixing material at least begins to fuse, so that it can be securely attached to the temporary support member.

A selective etching process is then performed on the upper surface of the donor sheet. This etching process can, in one embodiment involve first applying an upper layer of photo imageable material on the upper surface of the donor sheet. An upper photo mask can then be utilized along with a photo etching process to selectively remove portions of the photo imageable material. Some form of donor material etch resist material is then applied which fills photo etched away portions of the upper photo imageable material. Other methodologies for applying this etch resist could be utilized, such as print application of the etch resist directly onto the upper surface of the donor sheet. An etching process then occurs which etches away portions of the donor sheet adjacent the upper surface thereof. In one embodiment these etching regions are aligned with etching recesses in the lower surface of the donor sheet. In this way, die attach pads and terminal pads are fully isolated from each other by this second etching step.

The etch resist material can be removed from the upper surface if it is not electrically conductive or otherwise incompatible with desired characteristics for the upper surface of the pads formed by the donor sheet. A semiconductor, such as an integrated circuit can then be mounted upon the die attach pad, and wire bonds can be connected to the semiconductor device and to the upper surfaces of the terminal pads. Finally, the wire bonds, semiconductor device and pads are encapsulated with a substantially non-electrically conductive material, and the temporary support layer is removed, such as by peeling away. This removal of the temporary support layer can be assisted by applying heat sufficient to melt the fusible fixing material slightly so that it can be readily removed from the temporary support member, with or without a peeling motion between the temporary support member and other portions of the lead carrier. The lead carrier with temporary support member removed is then ready for testing and cutting into separate packages for mounting, typically through surface mount technology, to other portions of an electronic circuit within an overall electronic device where the semiconductor package is to be utilized.

### OBJECTS OF THE INVENTION

Accordingly, a primary object of the present invention is to provide a system for fabricating the electrical interconnect components of a semiconductor package that allows for the implementation of a simplified QFN process to more easily produce QFN packaged semiconductor dies.

Another object of the present invention is to provide a QFN fabrication process which is lower cost to put into practice.

Another object of the present invention is to provide a system and method for forming the electrical interconnect components of a semiconductor package arrayed on a sacrificial carrier that can be peeled away or otherwise separated after molding, to yield a continuous strip of multiple semiconductor packages with pads with no electrical connection between any two pads, to facilitate testing at various different stages of manufacture and avoidance of material waste.

Another object of the present invention is to provide the electrical interconnect components of a semiconductor package in a manner that enables higher electrical performance while utilizing a minimum amount of metal therein to facilitate electrical connection of a semiconductor die to the system board of an electronic system.

Another object of the present invention is to provide the electrical interconnect components of a semiconductor package that allow for the inclusion of more than two rows of input/output terminals and many times the number of input/output terminals than are practical with lead frame based QFN packages.

Another object of the present invention is to provide electrical interconnect components of a semiconductor package that allows greater design flexibility to incorporate features, such as multiple power and ground structures and multiple die attach pads, when compared to prior art lead frame based QFN packages.

Another object of the present invention is to provide a lead carrier with multiple integrated circuit mounting package sites thereon which can be manufactured in a low cost high quality manner.

Another object of the present invention is to provide a semiconductor package for electrical interconnection to adjacent components which is highly resistant to damage associated with shock loads thereto.

Another object of the present invention is to provide a lead carrier with multiple integrated circuit mounting package sites which exhibits high performance electrically by minimizing excess conducting portions therein.

Another object of the present invention is to provide a lead carrier which has package sites thereon which can be tested at multiple stages in the manufacturing process in a simple and automated fashion.

Another object of the present invention is to provide a semiconductor package manufacturing method which lends itself to high quality low cost mass production fabrication.

Other further objects of the present invention will become apparent from a careful reading of the included drawing figures, the claims and detailed description of the invention.

### BRIEF DESCRIPTION OF THE DRAWINGS

FIG. 1 is a perspective view of a QFN lead frame of a simplified variety and illustrating prior art lead frame technology.

FIG. 2 is a perspective view of a detail of a portion of that which is shown in FIG. 1, along with dashed lines indicative of where cut lines are followed to separate individual package sites from the lead frame.

FIG. 3 is a perspective view of a lead carrier according to this invention with multiple separate package sites thereon and mounted upon a temporary support member.

FIG. 4 is a perspective view of a detail of a portion of that which is shown in FIG. 3 and further illustrating details of each package site before mounting of an integrated circuit chip, attachment of wire bonds and encapsulation within mold compound.

FIG. 5 is a perspective view of a prior art QFN package showing placement of an integrated circuit chip and wire bonds and illustrating in broken lines how encapsulation material is placed relative to other conductive structures within the package.

FIG. 6 is a perspective view similar to that which is shown in FIG. 5 but with the encapsulating mold compound in place, and with portions of the encapsulating mold compound cut away to reveal interior structures of the package.

FIG. 7 is a perspective view similar to that which is shown in FIG. 6 but from below to illustrate solder joints available for surface mounting of the package upon an electronic system board or other interface within an electrical system.

FIG. 8 is a perspective view of an individual package site on the lead carrier of this invention after placement of an integrated circuit chip and wire bonds, and illustrating in broken lines the position of mold compound.

FIG. 9 is a perspective view similar to FIG. 8 but with the mold compound shown in place encapsulating conductive structures within the package, and with portions of the mold compound cut away to reveal interior details of the package.

FIG. 10 is a perspective view from below of the package and illustrating surface mount joints of the package according to this invention.

FIGS. 11-25 are full sectional views of steps in the process of forming the semiconductor supporting package according to this invention and illustrating the various layers and exemplary geometries for each package.

FIG. 26 is a perspective view of an alternative lead carrier with alternative pads illustrated having different edge contours to exhibit different engagement properties with surrounding encapsulating mold compound, and showing in perspective the configuration of individual pads according to this invention.

FIG. 27 is a full sectional view of further exemplary alternative pad geometry variations.

### DESCRIPTION OF THE PREFERRED EMBODIMENT

Referring to the drawings, wherein like reference numerals represent like parts throughout the various drawing figures, reference numeral 110 (FIG. 21) is directed to a finished lead carrier of a preferred embodiment. This lead carrier 110 includes a temporary support member 120 thereon, and is also embodied in a final package assembly 110′ after the temporary support member 120 has been removed.

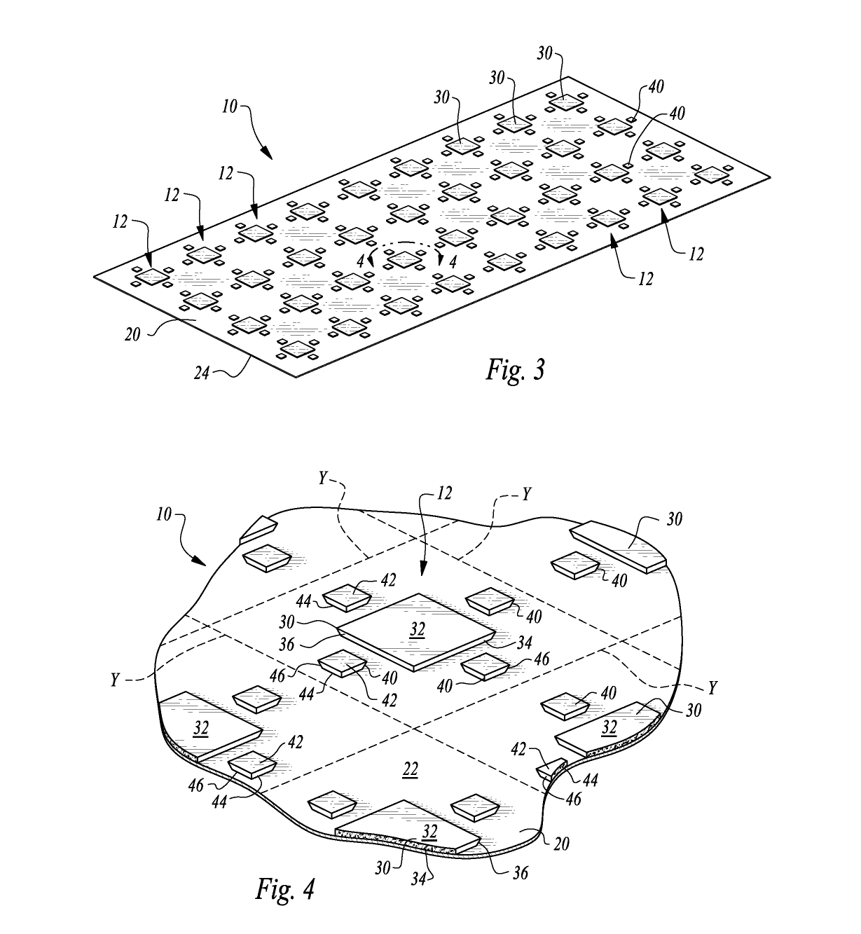

The lead carrier 110 is in some respects similar to the lead carrier 10 (FIGS. 3, 4 and 8-10) described herein above and the subject of U.S. patent application Ser. No. 13/135,210, incorporated herein by reference in its entirety. This related lead carrier 10 (FIGS. 3 and 4) is configured to support a plurality of package sites 12 thereon upon a temporary support member 20 for manufacture of a plurality of packages 100 (FIGS. 9 and 10) including an integrated circuit chip 60 and to provide for a large number of inputs and outputs into the integrated circuit chip 60.

In essence, and with particular reference to FIGS. 3, 4, 8 and 9, basic details are described for the lead carrier 10 and package 100 to which the lead carrier 110 of this invention is related. The lead carrier 10 includes a temporary support member 20 of thin planar high temperature resistant material, such as stainless steel. A plurality of die attach pads 30 and terminal pads 40 are arrayed on the temporary support member 20 at package sites 12, with multiple terminal pads 40 surrounding each die attach pad 30.

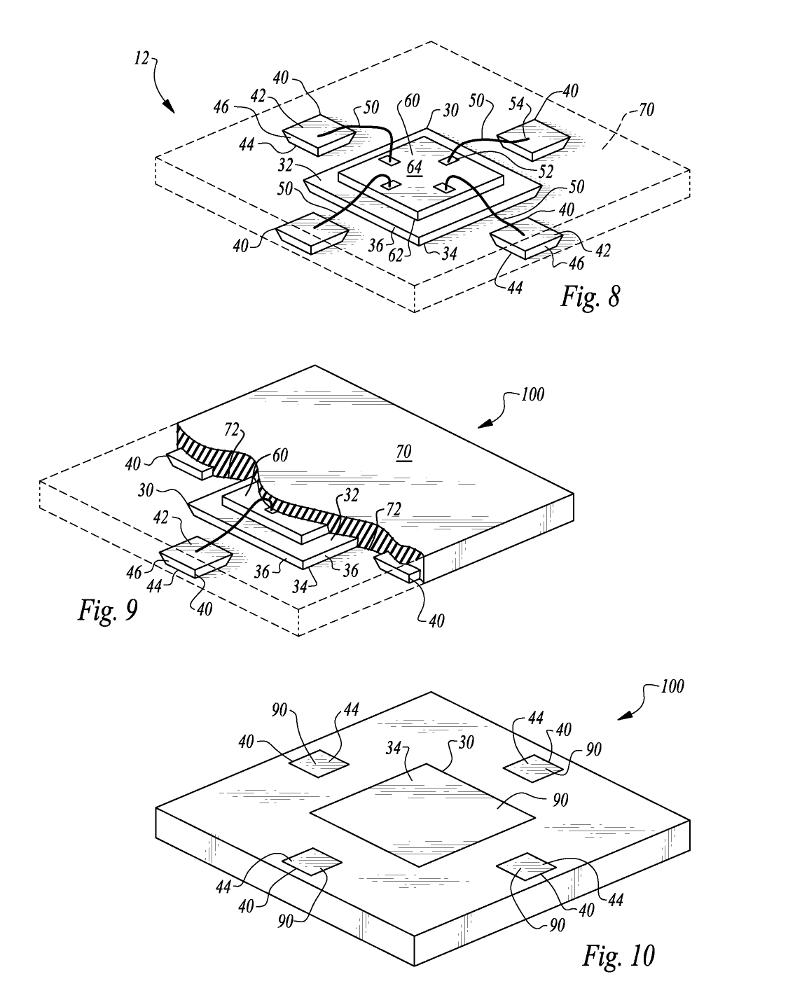

An integrated circuit chip 60 is mounted upon the die attach pad 30 (FIGS. 8 and 9). Wire bonds 50 are joined between input output terminals on the chip 60 and the terminal pads 40. The entire package 100 including the die attach pad 30, terminal pad 40, wire bonds 50 and chip 60 are encapsulated within a mold compound 70 other than surface mount joint 90 portions (FIG. 10) defining an underside of the package 100. The mold compound 70 is typically applied to the lead carrier 10 to surround each of the package sites 12. Later isolation of each package 100 occurs by cutting of the mold compound 70 to provide multiple packages 100 from the original lead carrier 10.

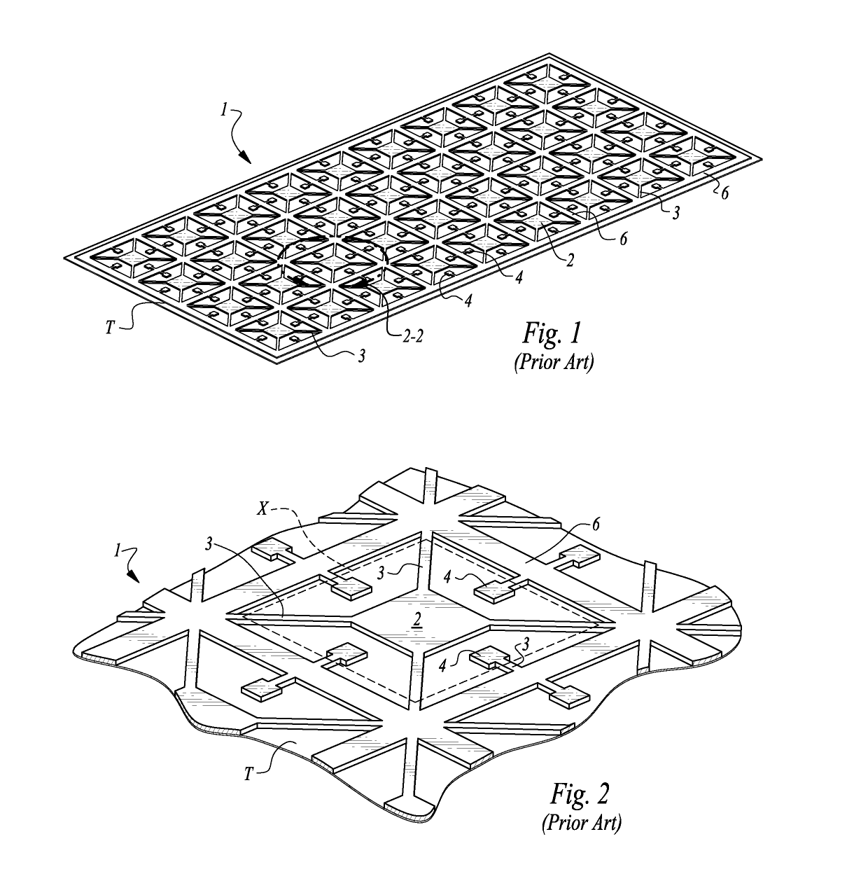

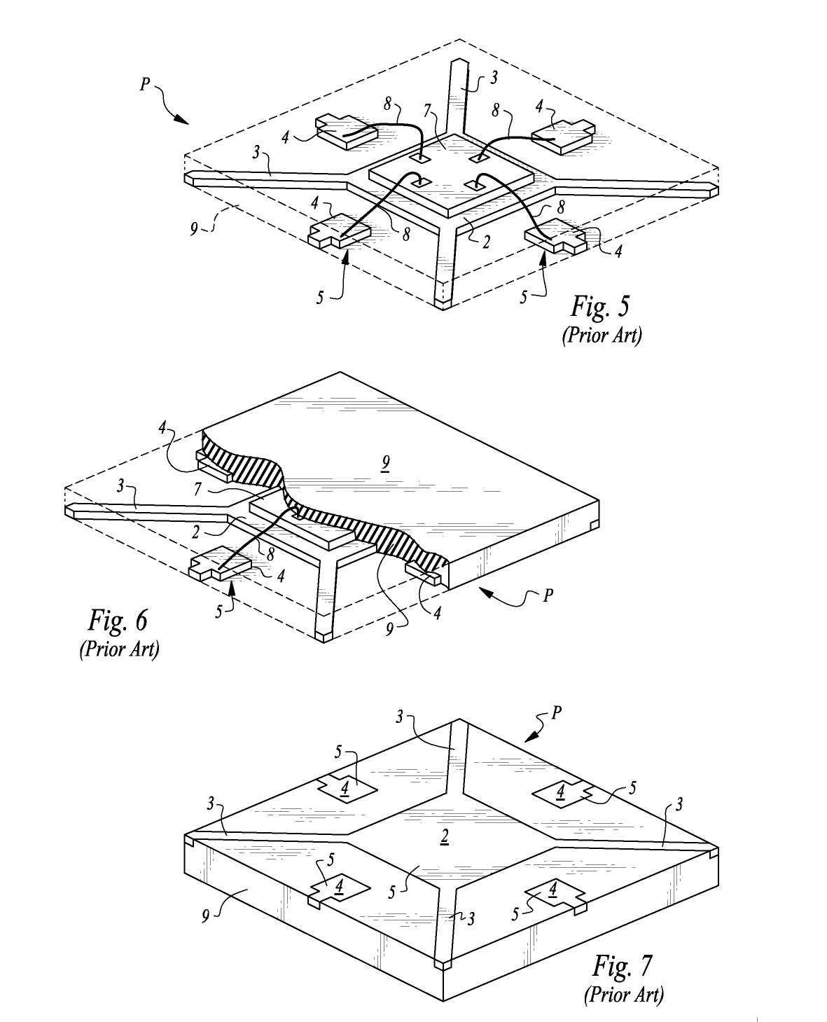

With particular reference to FIGS. 1 and 2, details of a prior art lead frame 1 of a “quad flat no lead” (QFN) variety are described for comparison and contrast to the details of the lead carrier 10. In the embodiment shown, the QFN lead frame 1 is a planar structure of etched conductive material. This etched conductive material is etched into distinct die attach pads 2 and wire bond pads 4, each joined to a common shorting structure 6 through tie bars 3. This entire etched QFN lead frame 1 is mounted upon molding tape T so that epoxy mold compound 9 can be applied to the lead frame 1 and encapsulate the pads 2, 4 (FIGS. 5-7).

Before such encapsulation, an integration of the chip 7 is mounted upon the die attach pad 2. Wire bonds 8 are placed between the wire bond pads 4 and input/output terminals on the chip 7. The mold compound 9 can then entirely encapsulate the pads 2, 4 as well as the chip 7 and wire bonds 8. The mold compound is prevented from encapsulating an underside of the pads 2, 4 by the tape T. After the mold compound 9 has hardened, the tape T can be peeled away so that solder joints 5 (FIG. 7) are presented on an underside of the lead frame 1. Finally, the separate QFN packages P are isolated by cutting (along cut lines X of FIG. 2) to isolate each package P from the overall lead frame 1.

Importantly, it should be noted that portions of the tie bars 3 extending from the die attach pads 2 and the wire bond pads 4 remain within the package P. Some portions of these tie bars 3 actually extend out of an edge of the package P (FIGS. 6 and 7). Furthermore, the common shorting structure 6 (FIGS. 1 and 2) is not part of any package P. Thus, the common shorting structure 6 is typically wasted. Furthermore, remaining portions of the tie bars 3 within each package P do not provide any beneficial purpose and hence are also wasted within the package P. Such tie bar 3 remnants can also have a negative impact on the performance of the package P and the chip 7 within the package P. For instance, a portion of the tie bars 3 extending out of edges of the mold compound 9 of the package P presents an opportunity for undesirable shorting or for electromagnetic interference and “noise,” such that certain electronics applications are not well served by prior art QFN packages P. Even when such prior art QFN packages P are suitable, waste associated with the common shorting structure 6 and tie bars 3 embedded within the package P is undesirable. Furthermore, the tape T is not reusable and is another wasted expense when utilizing known prior art QFN lead frame 1 and package P techniques (especially considering the non-recyclable and potentially hazardous nature of the tape T).

Referring to FIGS. 3 and 4, specific details of the lead carrier 10 as well as the temporary support member 20 and pads 30, 40 are described, according to an exemplary embodiment. This exemplary embodiment is significantly simplified over a typical preferred embodiment in that each package site 12 only shows four terminal pads 40 surrounding each die attach pad 30. Typically, such terminal pads 40 would be presented in numbers of dozens or potentially even hundreds surrounding each die attach pad 30. It is also conceivable that as few as one terminal pad 40 would be provided adjacent each die attach pad 30. Such terminal pads 40 would typically be presented in multiple rows including an innermost row closest to the die attach pad 30, an outermost row of terminal pads 40 most distant from the die attach pad 30 and potentially multiple intermediate rows between an innermost row and an outermost row of terminal pads 40.

The lead carrier 10 is a planar structure that is manufactured to include multiple package sites 12 and to support these package sites 12 during their manufacture and through testing and integration with integrated circuit chips 60 (or other semiconductor devices, such as diodes or transistors) and wire bonds 50 (FIGS. 8 and 9) to facilitate the ultimate production of multiple packages 100 (FIGS. 9 and 10). The lead carrier 10 includes a temporary support member 20. This temporary support 20 is a thin planar sheet of high temperature resistant material, most preferably stainless steel. This member 20 includes a top surface 22 upon which other portions of the lead carrier 10 are manufactured. An edge 24 of the temporary support member 20 defines a perimeter of the temporary support member 20. In this exemplary embodiment, this edge 24 is generally rectangular.

The temporary support member 20 is preferably sufficiently thin that it can flex somewhat and facilitate peeling removal of the temporary support member 20 from the lead carrier 10 (or vice versa) after full manufacture of packages 100 at the package sites 12 and lead carrier 10 (FIGS. 8-10).

The top surface 22 of the temporary support member 20 supports a plurality of package sites 12 thereon with each package site 12 including at least one die attach pad 30 and at least one terminal pad 40 adjacent each die attach pad 30. Cut lines Y generally define boundaries of each package site 12 (FIG. 4).

The die attach pads 30 and terminal pads 40 exhibit a different geometry and location, but are preferably formed of similar material. In particular, these pads 30, 40 are preferably formed of a sintered material. According to a preferred embodiment, these pads 30, 40 begin as a powder of electrically conductive material, preferably silver, mixed with a suspension component. This suspension component generally acts to give the silver powder a consistency of paste or other flowable characteristics so that the silver powder can best be handled and maneuvered to exhibit the desired geometry for the pads 30, 40.

A mixture of this suspension component and the silver powder or other electrically conductive metal powder is heated to a sintering temperature for the metal powder. The suspension component boils into a gas and is evacuated from the lead frame 10. The metal powder is sintered into a unitary mass having the shape desired for the die attach pads 30 and terminal pads 40.

The temporary support member 20 is configured to have thermal characteristics such that it maintains its flexibility and desired degree of strength and other properties up to this sintering temperature for the electrically conductive material forming the pads 30, 40. Typically this sintering temperature is approaching the melting point for the metal powder that is sintered into the pads 30, 40.

With particular reference to FIGS. 8-10, details of each package 100 after further manufacture upon the lead carrier 10 at the various package sites 12 are described, according to one exemplary embodiment. An integrated circuit chip 60 is mounted upon the die attach pad 30 typically with a lower side of the integrated circuit chip 60 electrically coupled to the die attach pad 30. Such electric coupling can be common to “ground” for the chip 60 or common to some other reference for the chip 60, or can have some other electrical state within an overall electrical system in which the package 100 is utilized. The chip 60 includes a base 62 defining a lower portion thereof in contact with the top side 32 of the die attach pad 30. An upper surface 64 of the chip 60 is provided opposite the base 62. This upper surface 64 has a plurality of input output junctions which can be terminated to one end of a wire bond 50 (FIGS. 8 and 9).

One wire bond 50 is preferably terminated between each input output junction on the chip 60 and a surrounding terminal pad 40. Thus, each wire bond 50 has a chip end opposite a terminal end. Using known wire bond 50 terminating techniques, such as those used with QFN lead frames, these wire bonds 50 are coupled between the chip 60 and the terminal pads 40.

To complete the package 100 forming process, mold compound 70 is flowed over the lead carrier 10 and allowed to harden in a manner completely encapsulating each of the die attach pads 30, terminal pads 40, wire bonds 50 and integrated circuit chips 60. This mold compound 70 can mold against the top surface 22 of the temporary support member 20. Thus, the surface mount joints 90 of each pad 30, 40 remain exposed after removal of the temporary support member 20 (FIG. 10). The mold compound 70 is typically of a variety which is a fluid form at a first temperature but which can harden when adjusted to a second temperature.

The mold compound 70 is formed of a substantially non-conductive material such that the pads 30, 40 are electrically isolated from each other. The mold compound 70 flows between the pads 30, 40 to provide interlocks which tend to hold the pads 30, 40 within the overall package 100 and together with the mold compound 70. Such interlocks keep the terminal pads 40 from becoming detached from the wire bonds 50. Such detachment propensity is first resisted when the temporary support member 20 is removed from the lead carrier 10, and again beneficially is resisted when the package 100 is in use and might experience shock loads that might otherwise detach the terminal pads 40 from the package 100. These interlocks can have a variety of different shapes as defined above associated with the edges of the pads 30, 40.

After hardening of the mold compound 70, the package 100 is provided in an array on the lead carrier 10 with each package 100 including a top 102 opposite a bottom 104 and with perimeter sides 106. Beneficially, the perimeter sides 106 are not required to have any electrically conductive material extending therefrom, in contrast to prior art QFN packages P (FIGS. 6 and 7), which must.

With particular reference to FIGS. 11-25, details of a method of manufacture of the lead carrier 110 and thereafter individual packaged semiconductor devices, is described, according to the preferred embodiment of this invention. The lead carrier 110 begins as merely a donor sheet 112. The donor sheet 112 has an assembly surface 114 upon which semiconductor devices, such as an integrated circuit chip 160 (FIG. 22) can be mounted, and to which interconnecting structures, such as the wire bond 150, can be attached (FIG. 23). An SMT mounting surface 116 is provided on an opposite side of the donor sheet 112 from the assembly surface 114. This mounting surface 116 is generally referred to as the lower surface and the assembly surface 114 is generally referred to as the upper surface.

The donor sheet 112 provides at least a portion, and typically a majority and most preferably substantially all of the electrically conductive material forming the die attach pads 130 and terminal pads 140 of the lead carrier 110. Materials from which the donor sheet 112 can be formed include copper, alloys of copper and metals and alloys of metals including nickel, iron, tungsten, palladium, platinum, gold, silver and aluminum. The material is selected to be highly electrically conductive and compatible with conventional processes for semiconductor die attach, gold or copper thermo sonic wave bonding and SMT soldering.

A fusible fixing material 119 is selectively applied to portions of the donor sheet 112 where the die attach pad 130 and terminal pad 140 are to be located. Materials which can provide the fusible fixing material 112 include tin and alloys of tin and other metals, alloys of gold, alloys of lead and other metals, and other metal alloys with melting temperatures between about 150° C. and 400° C. As another option, the fusible fixing material can be a polymeric composition or other material (i.e. a paraffin) which protects adjacent portions of the donor sheet 112 from oxidation or corrosion and having a similar range of temperatures.

The fusible fixing material 119 can be applied to the mounting surface 116 of the donor sheet 112 in a variety of different ways. For instance, the fusible fixing material could be provided as a powder along with some form of at least somewhat volatile binder liquid to form a flowable material. Such a flowable material can then be applied such as through a printing action, such as silkscreen printing action, or a spray printing action. Alternatively, some form of mold can first be applied and then the fusible fixing material in a flowable form can flow into the mold. As another alternative, the fusible fixing material can be caused to flow by heating the fusible fixing material to a temperature at which it melts into a liquid so that it can flow. If desired, some printing technology can be utilized which requires flowability characteristics so that the fusible fixing material can be applied where desired on the mounting surface 116 of the donor sheet 112.

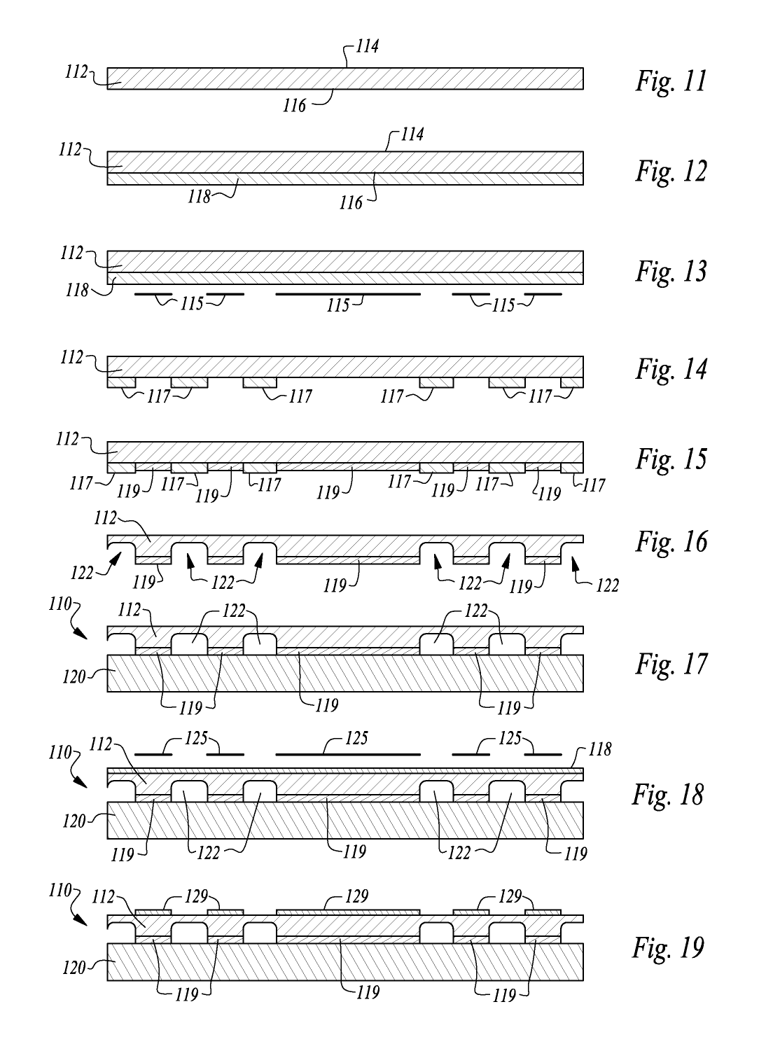

In this exemplary embodiment, the fusible fixing material 119 is applied to the mounting surface 116 as follows. Initially, a layer of photo imageable material 118 is applied to the mounting surface 116 of the donor sheet 112 (FIG. 12). Next, a photo mask 115 is located adjacent the photo imageable material 118 (FIG. 13). In this embodiment, the photo mask 115 is of a type which, when a photo etching radiation source is applied to the photo imageable material 118, causes removal of photo imageable material 118 adjacent where the photo mask 115 is located. As an alternative, the photo mask 115 could define locations where material is prevented from being removed when the photo radiation source is applied, in which case the photo mask 115 would have a “negative” geometry compared to that depicted in FIG. 13. The photo imageable material 118 is of a type which is hardened by the photo radiation if not covered by the photo mask 115, in this embodiment. As an alternative, the photo imageable material 118 can be of a type which causes it to be removed when experiencing the photo radiation.

In this embodiment, a developed photo imageable material 117 remains upon the mounting surface 116 of the donor sheet 112 after experiencing the photo radiation. This developed photo imageable material 118 is sufficiently hardened that it can function as a mold upon the mounting surface 116 so that the fusible fixing material 119 can be placed where desired within this mold. FIG. 14 depicts the developed photo imageable material 117 before placement of the fusible fixing material 119.

FIG. 15 depicts the donor sheet 112 after the fusible fixing material 119 has been placed into openings in the developed photo imageable material 119, or other form structure, to place the fusible fixing material 119 adjacent the mounting surface 116 of the donor sheet 112. Most preferably, such placement occurs by electroplating the fusible fixing material 119 upon the mounting surface 116 of the donor sheet 112. Other forms of deposition, such as electroless deposition could also be used. Alternatively, and as described above, the fusible fixing material 119 can be placed into the openings in the developed photo imageable material 117 by causing the fusible fixing material 119 to have a flowable character such as by heating it to above its melting point so that it is a liquid which can flow into the mold, or can be in the form of a powder with an appropriate solvent so that the fusible fixing material can flow, such as in the form of a paste, into openings in this mold. The fusible fixing material 119 is then allowed to harden, such as by allowing it to cool and return to a solid state, or to allow a flowable carrier or solvent component to volatilize or otherwise be removed, to leave the fusible fixing material 119 as a solid adjacent the mounting surface 116 of the donor sheet 112.

The next step in the process of forming the lead carrier 110 involves etching away portions of the donor sheet 112 between the various terminal pads 140 and die attach pad 130 associated with each package site on the lead carrier 110. In this embodiment such removal of intermediate material is performed through an etching process, and most preferably a chemical etching process. The etching process involves forming a lower etch recess 122 between terminal pads 140 and die attach pads 130.

To substantially restrict this lower etch recess 122 to these intermediate spaces, an etching material can be selected which does not etch into the fusible fixing material 119, such that the fusible fixing material 119 itself acts as an etch resistant material. As an alternative, some other form of etch resistant material can be applied to the fusible fixing material 119 on a lowermost surface thereof before said etching step. The etching material is selected which is capable of etching into the material forming the donor sheet 112. The lower etch recesses 122 thus extend into the donor sheet 112, and most preferably over half of a thickness of the donor sheet 112 (FIG. 16). By avoiding etching entirely through the donor sheet 112, the donor sheet 112 remains as a continuous sheet for all of the package sites of the lead carrier 110. It is conceivable that the lower etch recess 122 could extend entirely through the donor sheet 112 and that a support sheet could be temporarily bonded to the assembly surface 114 of the donor sheet 112.

After formation of the lower etch recess 122 between adjacent pads 130, 140, the donor sheet 112 with included fusible fixing material 119 is mounted upon a temporary support member 120 (FIG. 17). In a preferred embodiment this mounting process is accomplished by heating the fusible fixing material 119 to at least a fusing temperature for the fusible fixing material 119, which allows the fusible fixing material 119 to adhere to the temporary support member 120. This fusing temperature could be a temperature at which the fusible fixing material 119 is sinterable, such as a temperature at which surfaces of individual particles of the material are just beginning to melt such that bonding to adjacent structures can be facilitated. As an alternative, full or partial melting of the fusible fixing material 119 can be achieved with the fusible fixing material 119 thereafter cooled to harden and bond to the temporary support member 120.

Once the donor sheet 112 and associated fusible fixing material 119 have been securely attached to the temporary support member 120, further formation of the die attach pad 130 and terminal pad 140 can occur. In particular, and as depicted in FIGS. 18-20, a process similar to that described above with respect to FIGS. 13-16 can be followed to etch away remaining portions of the donor sheet 112 between die attach pads 130 and terminal pads 140. In at least one respect, this process of forming upper etch recesses 126 is distinct from the process described above. In particular, typically no fusible fixing material 119 is required for the assembly surface 114. Hence, rather than placing fusible fixing material 119 into openings formed in an upper photo imageable material 128 resulting from utilization of a photo mask 125, etch resist 129 is instead placed into such recesses.

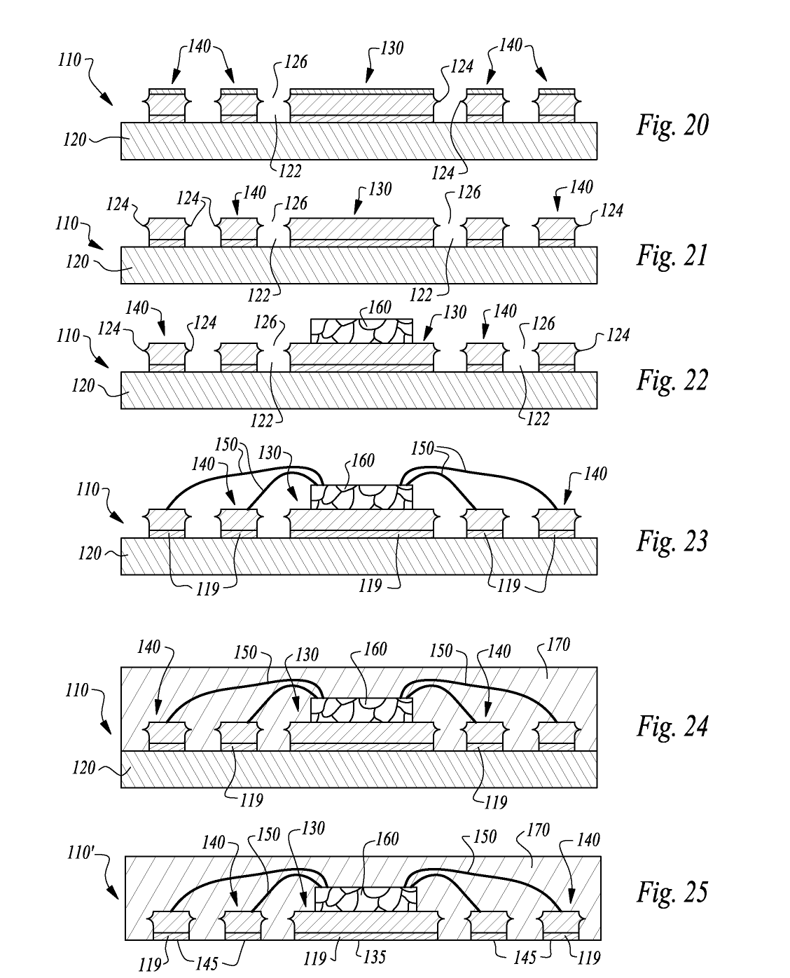

The upper etch recess 126 can then be formed by the assembly surface 114 of the donor sheet 112 coming into contact with etching material to form the upper etch recesses 126 whenever the etch resist 129 is not provided. The final result (FIG. 20) is separate terminal pads 140 and die attach pads 130 which are no longer electrically connected together and which are mounted upon a temporary support member 120. The etch resist 129 could be in the form of some form of relatively low melting temperature polymeric compound which does not chemically react with the etching material. The etching resist 129 material can then be removed (FIG. 21) such as by heating sufficiently to melt or volatilize the etch resist 129 away. If the etch resist 129 is electrically conductive and suitable for forming bonds with the wire bond 150 or an integrated circuit chip 160, it is conceivable that the etch resist 129 could remain rather than being removed.

One important attribute of the pads 130, 140 after the formation of the upper etch recess 126 is the formation of side fins 124 generally in a plane defining a deepest portion of the lower etch recess 122 and the upper etch recess 126. These fins 124 assist in holding the pads 130, 140 securely within the mold compound 170 (FIGS. 24 and 25) by causing a mechanical interlocking joint between the mold compound 170 and the pads 130, 140. Thus, rather than having to specifically provide a mold surface which is tapered or otherwise formed to create the side fins 124 or other mechanical locking features, the fins 124 naturally resulting from the two etch recesses 122, 126 provide the fins 124 merely as a result of the etching process and the general configuration of etching recesses which have rounded contours at deepest portions thereof.

At this stage, FIG. 21 depicts the lead carrier 110 in a form that is substantially complete, and ready for use as with other lead carriers, such as the lead carrier 10 (FIGS. 3 and 4) to form an assembly of semiconductor packages 110′ (FIG. 25) to be later separated into separate semiconductor packages. The lead carrier 110 has a plurality of package sites, each with at least one die attach pad 130 and at least one terminal pad 140 all mounted on the temporary support layer 120. The fusible fixing material 119 is in place between the temporary support layer 120 and the portions of the donor sheet 112 forming the pads 130, 140. This fusible fixing material both holds the pads 130, 140 to the temporary support layer 120 and protects the lower mounting surface 116 of the pads 130, 140 from oxidation or corrosion until they are ready to be used for surface mounting (after separation into separate packages) to other electronics. Not only does the fusible fixing material protect the pads 130, 140, but it can also be caused to readily release the temporary support layer 120 by application of heat to melt (at least partially) the fusible fixing material 119.

As depicted in FIGS. 22-24, an integrated circuit chip 160 or other semiconductor device is mounted upon the die attach pad 130 and wire bonds 150 are utilized to join the integrated circuit chip 160 to the terminal pads 140. Mold compound 170 is then provided which is of a substantially non-electrically conductive character to encapsulate all portions of the pads 130, 140, wire bonds 150 and integrated circuit chip 160, other than the lowermost portion of each pad 130, 140 defined by the fusible fixing material 119.

Finally, the temporary support member 120 is removed. Such removal can occur by applying a peeling force with the portions of the final package assembly 110′ other than the temporary support member 120 being more flexible than the temporary support member 120 and being locked together such as by the side fins 124, so that when this peeling force is applied the final package assembly 110′ cleanly removes from the temporary support member 120. Such removal can be facilitated by heating the entire assembly to a melting temperature for the fusible fixing material 119 to facilitate such removability. When such heating is utilized, the temporary support member 120 can conceivably be removed in a manner other than by a peeling motion, or both heating and peeling can be utilized together to most effectively achieve separation away from temporary support member 120. The remaining lead carrier 110′ without the temporary support member 120 includes the multiple package sites and is ready for testing and/or separation into separate semiconductor device packages. The final package assembly 110′ includes the fusible fixing material 119 covering the pads 130, 140 so that they are protected from oxidation or corrosion the package assembly 110′ can be substantially fully tested, for each package site, in this assembled state. The assembly 110′ can also be stored in this state without concern for oxidation or corrosion, and ready for further processing. Similarly, after separation of the assembly 110′ into individual packages, the pads 130, 140 of each package are protected from oxidation and corrosion and can be individually tested and stored until the packages are ready to surface mount or otherwise attach to an electronic circuit.

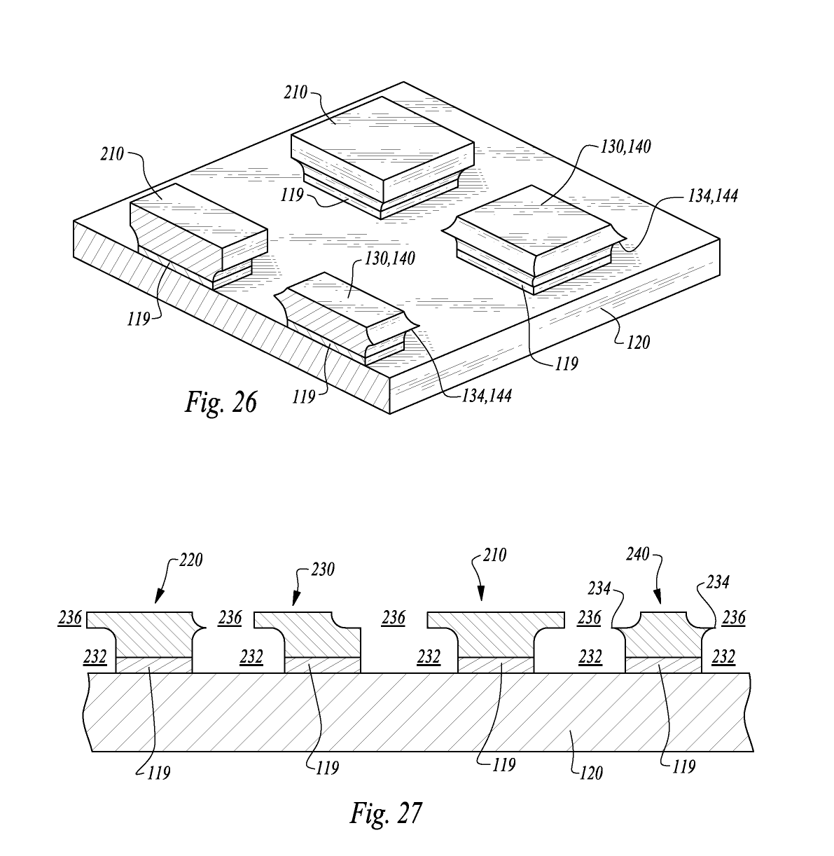

With particular reference to FIG. 26 the pads 130, 140 are shown upon a temporary support member 120 in perspective to further view their geometry. FIG. 26 also depicts an alternative attach pad generally referred to as a “mushroom” attach pad 210. With the mushroom attach pad 210, the upper etch recess 126 is aligned with the lower etch recess 122 but has a narrower form. In this way, more of the donor sheet 112 remains adjacent the assembly surface 114 than remains adjacent the mounting surface 116 and a built-in larger overhang results. Such an arrangement provides a greater degree of mechanical locking with the mold compound 170 and provides a greater surface area on the assembly surface 114, such as for supporting a semiconductor device thereon or for providing a surface to which wire bonds 150 can be attached.

With particular reference to FIG. 27, further variations on positioning and width of alternative lower etch recesses 232 and upper etch recesses 236 are described, and for providing variations on side fins 234. In one depicted embodiment a second alternative attach pad is provided in the form of an overhang attach pad 220. With the overhang attach pad 220, an overhang is provided on one side but a standard side fin 234 is provided on an opposite side.

A third alternative attach pad in the form of an offset attach pad 230 is also depicted in FIG. 27. With this third alternative offset attach pad 230, the assembly surface is shifted to one side relative to the mounting surface. FIG. 27 also depicts the mushroom attach pad 210 in a full sectional view.

Finally, FIG. 27 depicts a fourth alternative taper attach pad 240 which has a smaller assembly surface than its mounting surface by having the upper etch recess 236 wider than the lower etch recess 232, and still featuring side fins 234 thereon. Various combinations of different attach pads 210, 220, 230, 240, as well as other variations can be provided to deliver the particular geometry desired for the pads such as the pads 130, 140 within a semiconductor package being manufactured on the lead carrier 110. For instance, it might be desirable to have a die attach pad 130 which is larger on the assembly surface 114 and on the mounting surface 116 to accommodate the size of a larger integrated circuit chip 160, while minimizing space required on a mounting surface where the semiconductor package device is to be surface mounted onto other electronics, such as to conserve space on the other electronics platform. An offset attach pad might be beneficial where it is important that the upper portion of the terminal pad 140 be positioned in one particular location but with the mounting surface associated with the terminal pad 140 being in a slightly different position. With such an offset attach pad 230, such precise positioning can be accommodated.

This disclosure is provided to reveal a preferred embodiment of the invention and a best mode for practicing the invention. Having thus described the invention in this way, it should be apparent that various different modifications can be made to the preferred embodiment without departing from the scope and spirit of this invention disclosure. When structures are identified as a means to perform a function, the identification is intended to include all structures which can perform the function specified. When structures of this invention are identified as being coupled together, such language should be interpreted broadly to include the structures being coupled directly together or coupled together through intervening structures. Such coupling could be permanent or temporary and either in a rigid fashion or in a fashion which allows pivoting, sliding or other relative motion while still providing some form of attachment, unless specifically restricted.

What is claimed is:

1. A method for forming a lead carrier with multiple integrated circuit package sites thereon, each package site including at least one die attach pad for an integrated circuit and at least one terminal pad spaced from the die pad, the method including the steps of:
selecting a donor sheet of electrically conductive material;
coupling a fusible fixing material to a first surface of the donor sheet in a fusible fixing material pattern including portions of the at least one die attach pad and portions of the at least one terminal pad;
spacing the fusible fixing material portions of the die attach pad from the fusible fixing material portions of the at least one terminal pad;
etching the donor sheet away from the first surface at least partially into the donor surface on portions of the first surface of the donor sheet not covered by the fusible fixing material; and
attaching the fusible fixing material to a temporary support member on a side of the fusible fixing material opposite the donor sheet.

2. The method of claim 1 including the further steps of:
heating the fusible fixing material to the fusing temperature; and
separating the temporary support member from other portions of the lead carrier.

3. The method of claim 2 wherein said separating step includes the step of peeling the temporary support member away from other portions of the lead carrier.

4. The method of claim 2 including the further steps of:
mounting an integrated circuit upon a separate surface of the die attach pad opposite the fusible fixing material;
wire bonding the integrated circuit to the at least one terminal pad;
at least partially encapsulating the integrated circuit, wire bond and space between the at least one terminal pad and the at least one die attach pad with substantially non-electrically conductive mold compound; and
cutting the lead carrier into separate packages, each of the packages including at least one terminal pad and at least one die attach pad.

5. The method of claim 2 including the further step of testing the lead carrier electrically through the fusible fixing material portions of the lead carrier.

6. The method of claim 1 wherein said coupling step includes the steps of:
applying a photo imageable material to the first surface of the donor sheet;
selectively photo etching away portions of the photo imageable material defining a desired fusible fixing material pattern; and
filling etched away portions of the photo imageable material with fusible fixing material.

7. The method of claim 6 wherein said filling step includes flowing fusible fixing material particles into etched away portions of the photo imageable material and fusing the fusible fixing material particles together into a substantially rigid solid mass.

8. The method of claim 7 wherein said fusing step includes heating the fusible fixing material sufficiently to sinter the fusible fixing material into a solid unitary mass for each contiguous portion of the fusible fixing material pattern.

9. The method of claim 1 wherein said coupling step includes deposition of the fusible fixing material upon the first surface of the donor sheet by a process taken from the group of deposition processes including electroplating and electroless deposition.

10. The method of claim 1 wherein said attaching step includes heating the fusible fixing material to a fusing temperature, with the temporary support member formed of a material having a melting point higher than the fusing temperature for the fusible fixing material.

11. The method of claim 1 including the further step of further etching the donor sheet away from the second surface of the donor sheet opposite the first surface at least partially into the second surface of the donor sheet.

12. The method of claim 11 wherein said further etching step includes the steps of:
applying a photo imageable material layer to the second surface of the donor sheet;
selectively photo etching away portions of the photo imageable material defining a desired etch resist pattern; and
filling etched away portions of the photo imageable material layer with etch resist material.

13. The method of claim 12 wherein said further etching step follows a pattern similar to that of the fusible fixing material pattern such that substantially electrically isolated terminal pads and die attach pads remain after said further etching step.

14. The method of claim 1 wherein said etching step and said further etching step provide upper and lower etch recesses which are at least partially aligned with each other and with side surfaces of terminal pads and die attach pads adjacent the upper and lower etch recesses featuring a fin extending laterally at a junction between the upper etch recesses and the lower etch recesses.

15. A method for forming a lead carrier with multiple integrated circuit package sites thereon, each package site including at least one die attach region for an integrated circuit and at least one terminal pad spaced from the die attach region, the method including the steps of:
selecting a donor sheet of electrically conductive material;
coupling a fusible fixing material to a first surface of the donor sheet in a fusible fixing material pattern including portions of the at least one terminal pad;
spacing the die attach region from the fusible fixing material portions of the at least one terminal pad;
etching the donor sheet away from the first surface at least partially into the donor surface on portions of the first surface of the donor sheet not covered by the fusible fixing material; and
attaching the fusible fixing material to a temporary support member on a side of the fusible fixing material opposite the donor sheet.

16. The method of claim 15 including the further step of further etching the donor sheet away from the second surface of the donor sheet opposite the first surface at least partially into the second surface of the donor sheet.

17. The method of claim 16 wherein said further etching step includes the steps of:
applying a photo imageable material layer to the second surface of the donor sheet;
selectively photo etching away portions of the photo imageable material defining a desired etch resist pattern; and
filling etched away portions of the photo imageable material layer with etch resist material.

18. The method of claim 17 wherein said further etching step follows a pattern similar to that of the fusible fixing material pattern such that substantially electrically isolated terminal pads remain after said further etching step.

19. The method of claim 1 including the further steps of:
heating the fusible fixing material to the fusing temperature; and
separating the temporary support member from other portions of the lead carrier.

20. The method of claim 19 wherein said separating step includes the step of peeling the temporary support member away from other portions of the lead carrier.
